(19) United States
(12) Patent Application Publication
(10) Pub. No.: US 2026/0056248 A1
(43) Pub. Date: Feb. 26, 2026

(54) ELECTRONIC COMPONENT TEST METHOD OPTIMIZED BY A LEARNING ALGORITHM

(71) Applicant: BEALACH NA BO FINNE TEORANTA, DUBLIN 2 (IE)

(72) Inventor: Philippe LEJEUNE, FLORESSAS (FR)

(21) Appl. No.: 19/102,354

(22) PCT Filed: Aug. 2, 2023
(86) PCT No.: PCT/EP2023/071377

§ 371 Date: Feb. 7, 2025

(30) Foreign Application Priority Data
Aug. 8, 2022 (FR) FR2208165

(51) Int. Cl. G01R 31/28; G01R 31/317

(52) U.S. Cl. CPC G01R 31/2846; G01R 31/2894; G01R 31/31725

(57) ABSTRACT

An electronic component test method. A component is excited and after a reduced wait time, an anticipatory response of this component is measured. A stabilized response is estimated, corresponding to a response that would have been measured after a nominal wait time, based on the anticipatory response. An acceptance condition is verified, for the estimated stabilized response value, for assessing the quality of the component. The estimation is carried out by a learning algorithm, previously trained by, measuring several response values of each component of a set of reference components, for each wait time, during a progressive decrease of the wait time. Based on the measurements obtained, the reduced wait time is determined, and the learning algorithm is trained to estimate a stabilized response value.

### TECHNICAL FIELD OF THE INVENTION

The invention relates to an electronic component test method optimized by a learning algorithm. The invention is intended for an application in the field of electronic component and/or semiconductor production.

Electronic component production sites need to check the proper operation of components in order to integrate them in a product further downstream in the production line. Indeed, late detection (close to the finished product) of a defective component gives rise to greater productivity losses than early detection.

However, as the duration of these tests is added to those of the production line, overall productivity is found to be nonetheless reduced.

The aim of the present invention is that of providing an electronic component test method with the shortest possible duration of execution without degrading production quality.

### PRIOR ART

There are several approaches for reducing the time devoted to electronic component tests. In particular, by setting up or increasing the level of parallel testing, carrying out several tests simultaneously on a component or carrying out a test on several components simultaneously or a combination of both make it possible to save time. However, this approach involves relatively heavy investments in test infrastructure for the production line, the installation of several parallel testing systems or more enhanced testing systems.

Another approach consists of setting up or increasing sampling, indeed, by means of different empirical and/or statistical methods, some tests can be considered as superfluous and removed from the test method carried out on each component. By reducing the number of tests carried out on the components, the overall time devoted to the tests is decreased. Similarly, the number of components tested can be adjusted, a group of components can be considered as being of good or poor quality based on the test result of a certain number of components in this group. Indeed, these so-called sampling approaches have the advantage of reducing the time devoted to tests without incurring particular investment. However, they result from a sometimes risky compromise on the overall quality of the components used downstream in the line. The test coverage being reduced, to save time, the risk of defective components not being detected or being detected late, during tests on the finished product for example, remains present.

Another approach proposes reducing the unit time of each test in different ways. Some production lines may choose to use one or more of these approaches according to different combinations. Carrying out a test on an electronic component very predominantly involves the following steps:
subjecting at least one of the terminals of the component to an excitation,
measuring, after a wait time, a response value to at least one of the terminals of this component,
comparing the response value to acceptance limits to assess the quality of the component.

Reducing the unit time of each test consists of reducing this wait time between the excitation and the measurement. This type of approach indeed makes it possible to reduce the time devoted to tests without additional investment in testing means and without degrading test coverage.

This approach consists of reducing the wait time, from a nominal wait time, which is generally provided by the manufacturer and includes a safety margin, without the response value of the component changing significantly.

This approach can subsequently be enhanced, by adjusting the wait time, according to a compromise aimed at not overly degrading the reliability of the tests, i.e., so as to only generate a very small number of inaccurate results (good-quality components deemed to be of poor quality or conversely poor-quality components deemed to be of good quality) during test execution.

### DISCLOSURE OF THE INVENTION

The present invention consists of enhancing this approach further by reducing the wait time additionally without degrading the reliability of the tests by providing a test method optimized by a learning algorithm.

To this end, and according to a first aspect, the electronic component test method includes the following steps:
excitation of at least one of the terminals of a component,
measuring, after a reduced wait time, an anticipatory response value to at least one of the terminals of the component,
estimating a stabilized response value, corresponding to a value that would have been measured after a nominal wait time (greater than said reduced wait time), based on the anticipatory response value,
verifying an acceptance condition, for the estimated stabilized response value, for assessing the quality of the component.

The estimation of said stabilized response value based on said anticipatory response value is carried out by a learning algorithm previously trained, during a learning phase, according to the following steps:
determining a set of reference components including one or more components,
decreasing the wait time iteratively from said nominal wait time,
measuring several response values of each component of the set of reference components, for each wait time,
determining the reduced wait time based on the measurements obtained,
using the measurements obtained as learning data to train the learning algorithm to estimate a stabilized response value, corresponding to a value that would have been measured after the nominal wait time, based on an anticipatory response value measured at the reduced wait time.

Set of reference components means one or more electronic components for which the quality is deemed to be satisfactory.

Component of satisfactory quality, for example, means that the response value at the nominal wait time is within a validity range composed of one or more acceptance limits, for a certain number of successive tests.

Component of satisfactory quality, for example, means that the estimated stabilized response value is within a validity range composed of one or more acceptance limits, for a certain number of successive tests.

The present test method makes it possible to reduce additionally the time required for testing an electronic component relative to a test method as found in the prior art without stabilized response values estimation.

The test method of the present invention also makes it possible to reduce the time of an electronic component test without modifying the acceptance conditions, generally provided by the component manufacturer.

In particular implementations, the invention may further include one or more of the following features, taken individually or according to any technically possible combinations.

According to one implementation, determining said reduced wait time based on the measurements obtained includes the following steps:
defining at least one metric for which a value is determined, for a given wait time, based on at least a portion of the response values measured at said given wait time,
determining a value of said at least one metric for the nominal wait time,
for each wait time less than the nominal wait time:
   determining a value of said at least one metric for said wait time,
   verifying a reduction condition according to the value of said at least one metric for the nominal wait time and the value of said at least one metric for said wait time.

The reduced wait time is greater than or equal to the shortest wait time from which the reduction condition is fulfilled and less than or equal to the nominal wait time.

Said at least one metric can include for example a mean and a variance used together.

The value of said at least one metric is determined based on a portion of the response values because it is sometimes useful to filter certain response values (for example, response values deemed to be outliers).

“Each wait time less than the nominal wait time” means wait time values obtained, for example, iteratively by successive reductions of the wait time by a time step value.

Thanks to the reduction condition, which indicates whether the wait time reduction associated with a given wait time is valid, the test method reliability is maintained at a satisfactory level.

Test method reliability means the confidence that can be placed in the test results, a good test method reliability implies that the test method generates few inaccurate results (poor-quality components deemed to be of good quality or conversely good-quality components deemed to be of poor quality).

According to one implementation, said at least one metric includes a variance.

The use of a variance as a metric makes it possible to reduce the wait time additionally with respect to the use of a metric such as the mean for example. Indeed, the mean value at the reduced wait time can move significantly away from the mean value at the nominal wait time without the variance changing significantly.

According to one implementation, the learning algorithm is a machine learning algorithm. The use of a machine learning algorithm makes it possible to build the method for estimating and/or determining the reduced wait time using a large amount of information. This large amount of information, which can be based on numerous measurements on numerous components, thus increases the representativeness of the estimation method and the quality of the compromise between time-saving and test reliability.

According to one implementation, the learning algorithm carries out at least one interpolation. By interpolating the data obtained from the different measurements, the test method can thus be adapted to measurement points (response value and wait time pair) missing from the learning data.

According to one implementation, the interpolation is a polynomial interpolation and/or a cubic spline type interpolation. Polynomial interpolation is an interpolation method which, once the interpolation polynomial has been established, facilitates the retention of this interpolation in memory because only saving the coefficients of the degrees of the polynomial allows subsequent reconstruction of this polynomial. Cubic spline type interpolation allows a good representativeness of the interpolation thus carried out. This means that the estimations carried out based on this interpolation will be similar to the behavior that an electronic component would have had at the estimated measurement point. Cubic spline type interpolation is a piecewise polynomial interpolation using third-degree polynomials.

According to one implementation, the learning algorithm carries out an interpolation between measurement points corresponding to different wait times in order to obtain a response value function according to the wait time. This makes it possible to estimate the response value that would have been obtained after a nominal wait time based on response values for wait times at which no measurement would have been made during the learning phase.

According to one implementation, the learning algorithm carries out an interpolation between measurement points at a given wait time in order to obtain a function of the response value that would have been obtained after a nominal wait time based on a response value and wait time pair. This makes it possible to estimate the response value that would have been obtained after a nominal wait time based on anticipatory response values that would not have been measured during the learning phase.

According to one implementation, the test method also includes a wait time relaxation phase, replacing the reduced wait time by a relaxed wait time. The relaxed wait time is a wait time for which the value is greater than the reduced wait time while remaining less than the value of the nominal wait time. Indeed, the test environment on each production line using the test method is necessarily different from the test environment used during the learning phase (generally a laboratory). These differences in environment can cause a poor adaptation of the reduced wait time to a production line using the test method. A wait time relaxation phase makes it possible to retain satisfactory reliability of the test method despite these differences in environment.

According to one implementation, the relaxation phase includes the following steps:
determining another set of reference components for relaxation including one or more components,
measuring several response values of each component of the set of reference components for relaxation at the nominal wait time,
increasing the wait time iteratively from said reduced wait time,
measuring several response values of each component of the set of reference components for relaxation, for each wait time,
determining said relaxed wait time based on the measurements obtained.

Measuring several response values for different wait times during the relaxation phase makes it possible to correctly characterize the test environment on the production line and thus adjust the wait time in the most adapted manner to this environment.

According to one implementation, determining the relaxed wait time includes the following steps:
defining at least one relaxation metric for which a value is determined, for a given wait time, based on at least a portion of the response values measured at said given wait time,
determining a value of said at least one relaxation metric for the nominal wait time,
for each wait time greater than or equal to the reduced wait time:
   determining a value of said at least one relaxation metric for said wait time,
   verifying a relaxation condition according to said at least one relaxation metric for the nominal wait time and said at least one relaxation metric for said wait time.

The relaxed wait time is greater than or equal to the shortest wait time from which the relaxation condition is fulfilled and less than or equal to the nominal wait time.

The value of said at least one relaxation metric is determined based on a portion of the response values because it is sometimes useful to filter certain response values (for example, response values deemed to be outliers).

“Each wait time greater than the nominal wait time” means wait time values obtained, for example, iteratively by successive increases of the wait time by a time step value.

Thanks to the relaxation condition, if the test environment on the production line triggers the need, the test method reliability is readjusted.

According to one implementation, said at least one relaxation metric includes a variance.

Using a variance as a relaxation metric makes it possible to limit the increase of the wait time during the relaxation phase with respect to other types of metrics.

According to a second aspect, the invention relates to a device including at least one test module, at least one processor controlling said test module and at least one electronic memory wherein a computer program product is stored in memory in the form of a set of code instructions to be run to implement the steps of one of the implementations of the test method.

Such arrangements allow the device to carry out the test method and optionally the relaxation phase.

Test module means a module equipped with interfaces configured to selectively apply excitations to the interfaces, also referred to as terminals, of an electronic component and to measure responses of the electronic component. The excitations can for example take the form of electrical signals. The interfaces are, for example, electrodes. The responses measured are, for example, electrical signals, in particular voltage values.

According to a third aspect, the invention relates to a device including at least one test module, at least one processor controlling said test module and at least one electronic memory wherein a computer program product is stored in memory in the form of a set of code instructions to be run to implement one of the following steps:
determining a set of reference components including one or more components,
decreasing a wait time iteratively from a nominal wait time,
measuring several response values of each component of the set of reference components, for each wait time,
determining a reduced wait time based on the measurements obtained,
using the measurements obtained as learning data to train a learning algorithm to estimate a stabilized response value, corresponding to a value that would have been measured after the nominal wait time, based on an anticipatory response value measured at the reduced wait time.

Such arrangements allow the device, according to the third aspect of the invention, to train the learning algorithm carrying out the estimation of the stabilized response value based on the anticipatory response value. Said learning algorithm characterizes the test method according to the first aspect of the invention.

### BRIEF DESCRIPTION OF THE FIGURES

The invention will be better understood upon reading the following description, given as a non-limiting example, and made with reference to the figures:

FIG. 1 is a schematic representation of a first example of electronic component test method according to the invention,

FIG. 2 is a schematic representation of an example of a determination of a reduced wait time,

FIG. 3 is a schematic representation of a second example of electronic component test method according to the invention,

FIG. 4 is a representation of the curves obtained based on the measurements made during a learning phase,

FIG. 5 is a representation of the evolution, as a function of the wait time, of the sum of a mean and the square of a variance of the response values measured during a learning phase,

FIG. 6 is a representation of reference curves and an estimated curve according to an example of an estimation of a stabilized response value,

FIG. 7 is a schematic representation of an example of electronic component test method according to the invention including a relaxation phase,

FIG. 8 is a schematic representation of an example of a determination of a relaxed wait time,

FIG. 9 is a representation of a device according to the invention including a test module, a processor and a memory; and

FIG. 10 is a representation of another device according to the invention including a test module, a processor and a memory.

In these figures, identical references from one figure to another refer to identical or similar elements. For clarity, the represented elements are not necessarily to the same scale, unless stated otherwise.

### DETAILED DESCRIPTION OF PARTICULAR EMBODIMENTS OF THE INVENTION

FIG. 1 schematically represents an example of test method according to the invention. The excitation step 4 during which at least one terminal or a component is subjected to an excitation is represented. Excitation means, for example, sending an electrical signal. After this excitation step 4, a step of waiting 5 for a reduced wait time is represented. This reduced wait time is determined during a learning phase 3. After waiting for the reduced wait time, a measurement step 6 is carried out. During this step, the response of the electronic component to the excitation is measured, or recorded, or observed. This generally consists of measuring a value of an electrical signal at at least one terminal of the component.

An estimation step 7 is then represented. During this step, information provided by the learning phase 3 is used to calculate a response value that would have been measured at at least one terminal of the component after a nominal wait time based on the response value of the component, measured after the reduced wait time. “Nominal wait time” means a wait time used to test the electronic component, defined empirically and including a substantial safety margin. The verification step 8 is then represented, during this step, an acceptance condition is assessed according to the response value estimated during the preceding step 7. The acceptance condition makes it possible to assess the quality of the tested component and, for example, determine whether the component can be integrated downstream in an assembly line. Several acceptance conditions are possible, they can consist for example of verifying that the estimated response value is greater than a predetermined threshold or, that it is within a range of values. The learning phase 3, represented at the start of the test method, can also be carried out independently to carrying out the method, in the most frequent case, the learning phase is carried out in a laboratory using a sample of components of a certain model. This learning phase is then used to configure a test method according to the invention which will be carried out in very numerous iterations in assembly lines using said electronic component model or in production lines of said electronic component model.

The sub-steps of the learning phase 3 are represented in FIG. 1. The learning phase 3 starts with a step 31 of determining a set of reference electronic components. During this step, electronic components are subjected to a test method wherein the wait time is nominal, only electronic components for which the quality is deemed to be satisfactory are selected to form the set of reference components used by the learning phase. The set of reference components is sometimes referred to as “reference set” hereinafter in the description.

After the step of determining 31 the set of reference electronic components, three counters are initiated. The component counter n_{comp} at 1; the wait time counter t at tₙₒₘᵢₙₐₗ, tₙₒₘᵢₙₐₗ being the nominal wait time indicated, for example, by the component manufacturer, for carrying out an electronic component test; and the number of measurements counter nₘₑₐₛᵤᵣₑ at 1. Then, the steps of excitation 32, waiting 33 for a time t and measurement 34 are carried out. The number of measurements counter is then incremented, then steps 32, 33 and 34 are repeated to obtain another measurement of the same point (i.e. for the same component and the same wait time).

Once the number of measurements made reaches a predetermined value maxₘₑₐₛᵤᵣₑ the wait time t is decreased by a predetermined time step Δt and a number of new measurements equal to maxₘₑₐₛᵤᵣₑ is carried out again. The value of the number maxₘₑₐₛᵤᵣₑ and the value of the time step Δt are for example defined by an engineer in charge of learning.

Once the condition 35 “t=tₘᵢₙ” is reached, the component counter n_{comp} is incremented and the wait time is reset to the nominal wait time tₙₒₘᵢₙₐₗ. The response values for the different iterations and the different wait times are measured for each component of the reference set, max_{comp} being the number of components in the reference set.

In one implementation example, the shortest wait time tₘᵢₙ for which response values of a component are measured during the learning phase is a time proportional to the nominal wait time. For example:

$${t}_{min} = 0.1 \times {t}_{nominal} \qquad [ Math . 1 ]$$

Once all the measurements have been made on the components of the reference set, the steps of determining the reduced wait time 36 and training 37 the learning algorithm are carried out to allow the estimation 7 of stabilized response values based on anticipatory response values. “Anticipatory response values” means the response values of a component measured after a reduced wait time.

In one implementation example, the determination 31 of the set of reference components can be carried out simultaneously with the steps of excitation 32, waiting 33 for the nominal wait time tₙₒₘᵢₙₐₗ and measurement 34 because identifying a component of quality deemed to be satisfactory to form the reference component set consists of testing the component with a wait time equal to the nominal wait time tₙₒₘᵢₙₐₗ.

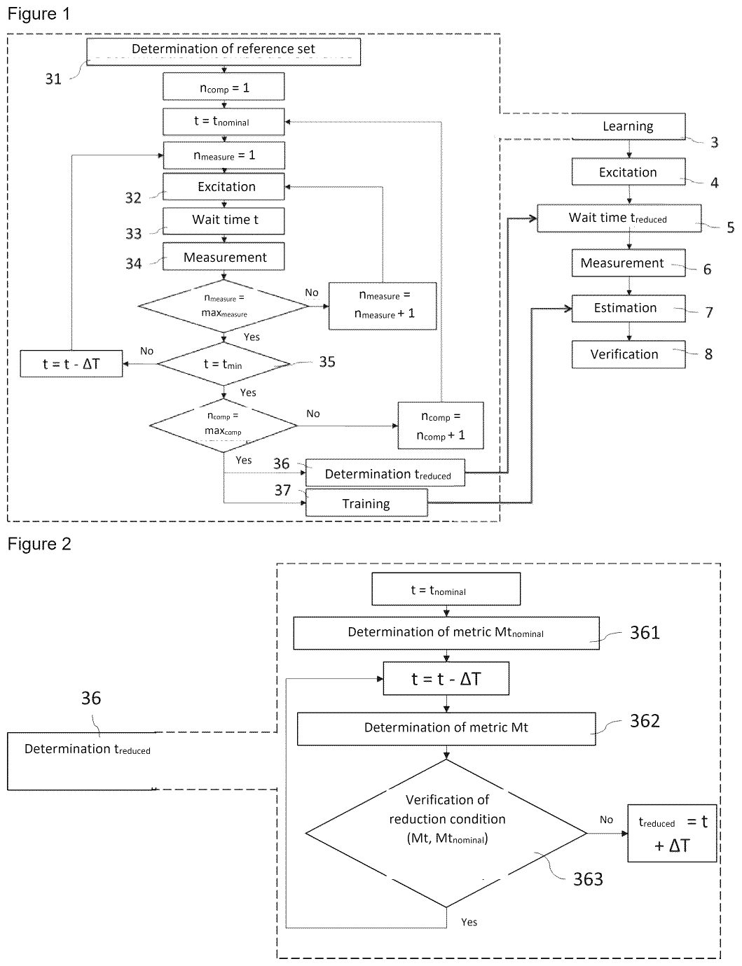

FIG. 2 schematically represents an example of determination 36 of the reduced wait time t_{reduced}. A step of determining 361 a value of a metric, based on the response values of the component of the reference set at the nominal wait time, is represented. The metric determined during the step 361 may be a mean of the response values or a variance of the response values or a standard deviation of the response values. Not all the response values will necessarily be used to calculate the metric, the values deemed to be outliers may for example be excluded, only a portion of the response values at a given wait time may therefore be used to calculate the metric. Then, during a progressive decrease in the wait time t (according to the time step Δt), a step of determining 362 a value of the metric, based on the response values of the components of the reference set at the wait time t, is carried out. Then, a step of verifying 363 a reduction condition, established based on previously determined metrics, is carried out. The reduced wait time is the shortest wait time from which the reduction condition is fulfilled.

In one implementation example, several metrics are determined and a combination of these metrics is then used to establish the reduction condition.

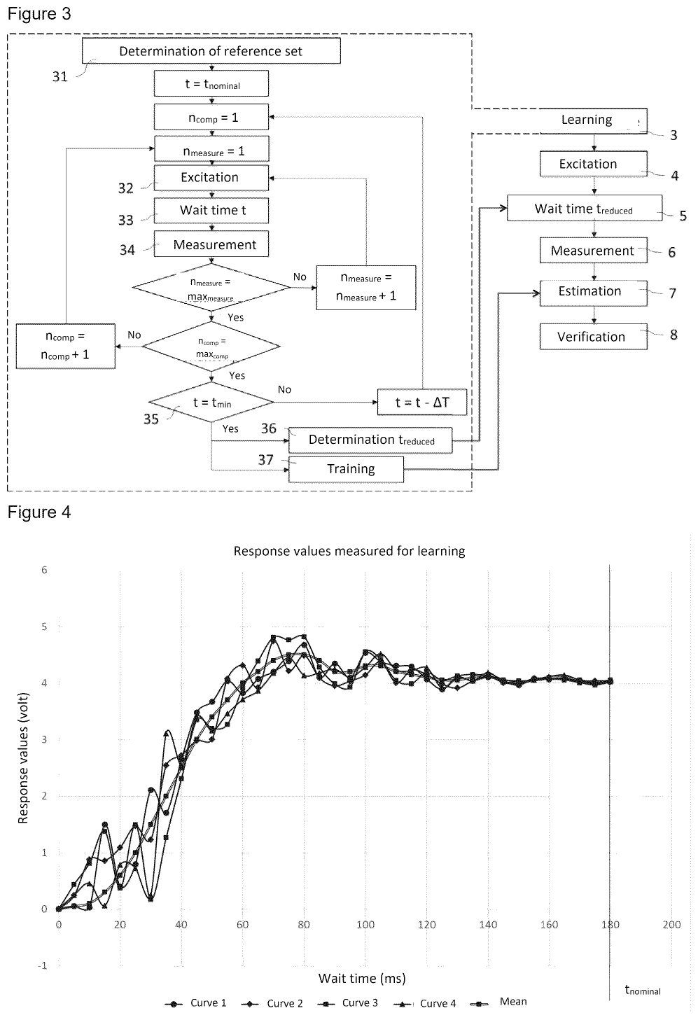

FIG. 3 schematically represents another example of test method according to the invention. It consists substantially of the same example as that represented in FIG. 1, except that the response values of all the components of the reference set are measured before decreasing the wait time. This embodiment example is well adapted to a test environment for learning allowing parallel testing of several components.

In this implementation example, tₘᵢₙ can be defined as being the last wait time (during a progressive reduction of said wait time) for which the absolute value of the difference between a mean of the response values of one or more components of the reference set at the nominal wait time and a mean of the response values of one or more components of the reference set at said wait time is less than or equal to a threshold. tₘᵢₙ is therefore the last wait time t for which the following inequality is true:

$$\vert {Mt}_{nominal} - Mt \vert \leq Threshold \qquad [ Math . 2 ]$$

Mtₙₒₘᵢₙₐₗ is a mean of the response values of one or more components of the reference set at the nominal wait time. Mt is a mean of the response values of one or more components of the reference set at said wait time.

In one implementation example, the acceptance condition making it possible to assess the quality of a component is defined by an upper limit value and a lower limit value. The threshold may be defined according to the lower and upper limit values. For example,

$$Threshold = 0.1 \times ( {V}_{bUpper} - {V}_{bLower} ) \qquad [ Math . 3 ]$$

V_{bLower} is the lower limit value and V_{bUpper} the upper limit value.

In one implementation example, the shortest wait time tₘᵢₙ for which the measurements are made during the learning phase is equal to the reduced wait time t_{reduced}, used in the test method after the learning phase. In this case, the steps of determining 36 the reduced wait time and verifying the condition 35 are carried out simultaneously. In this case also, the at least one metric is therefore the mean of the response values at a given wait time. In one implementation example, the shortest wait time tₘᵢₙ for which the measurements are made during the learning phase is equal to the reduced wait time t_{reduced} and the at least one metric is the variance of the response times at a given wait time.

Measuring response values for the least different wait times possible during the learning phase makes it possible to limit the duration of the learning phase. In this case, it is advantageous that the shortest wait time tₘᵢₙ for which measurements are made during the learning phase be equal to the reduced wait time t_{reduced}. However, it is sometimes advantageous to measure response values for a broader wait time range in order to better characterize the component and therefore potentially improve the quality of the estimations during the step 7 of the test method. The two wait times tₘᵢₙ and t_{reduced} are therefore not necessarily identical.

FIG. 4 represents an example of response value curves obtained following the measurements made during the learning phase 3. A mean curve can be established based on the means of the response values at each wait time. In this example, the time step Δt is 5 ms and the nominal wait time tₙₒₘᵢₙₐₗ 180 ms.

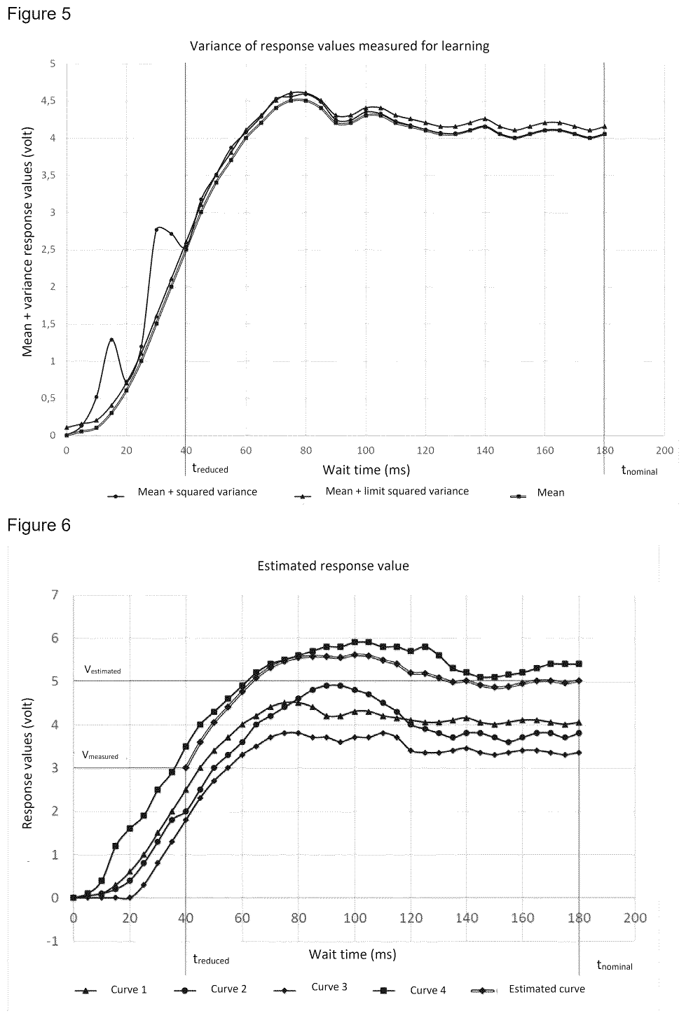

FIG. 5 represents values of a metric calculated based on the response values represented in FIG. 4. The mean curve can be seen along with a curve representing the evolution of the sum of the mean and the square of the variance of the response values according to the wait time. In addition, a curve represents the sum of the mean and the square of the variance of the response values at the nominal wait time multiplied by a coefficient.

In this implementation example, the reduced wait time is the shortest wait time from which the square of the variance of the response values at said wait time is less than or equal to the square of the variance of the response values at the nominal wait time multiplied by a coefficient.

In this example, the metric corresponds to the variance of the response values at a given wait time, and the reduction condition is defined as follows:

$${S}_{t} \leq Coef \times {S}_{nominal} \qquad [ Math . 4 ]$$

Sₜ being the variance of the response values measured at the wait time t and Sₙₒₘᵢₙₐₗ the variance of the response values measured at the nominal wait time. The value of the coefficient used in the reduction condition is established, for example, by an engineer in charge of learning. It can amount to a value of 150 for example.

The square of the variance S of the response values for a given wait time being calculated, in this implementation example, as follows:

$${S}^{2} = \frac{{\sum }_{i = 1}^{n} {( M - {V}_{i} )}^{2}}{n - 1} \qquad [ Math . 5 ]$$

n being the number of measurements at the given wait time, Vᵢ being the response value of a component at the given wait time obtained during the measurement of index i and M being the mean of the n response values measured at the given wait time.

FIG. 5 shows the reduced wait time as being the last wait time, when the wait time is decreased progressively from the nominal wait time, for which the reduction condition is fulfilled. This means, in this case, the wait time for which the curve, representing the evolution of the sum of the mean and the square of the variance (referred to as “Mean+squared variance” in the figure), passes above the curve representing the sum of the mean and the square of the variance at the nominal wait time multiplied by a coefficient (referred to as “Mean+limit squared variance” in the figure).

In one implementation example, the reduced wait time can be greater that the shortest wait time from which the reduction condition is fulfilled in order to retain a margin of error to ensure satisfactory reliability of the test method.

FIG. 6 represents an example of difference response value curves obtained following the measurements made during the learning phase 3, as well as a curve estimated based on a response value measured during the test of a component in the production or assembly line (corresponding to a measurement 6 of the test method). In one implementation example, the different measurement points for discrete wait times can be used to build a curve thanks to a polynomial interpolation. Curves 1 to 4 are built thanks to points, obtained from the measurements made for different wait times during the learning phase, linked by a cubic spline type interpolation. This consists of an interpolation between measurement points at different wait times.

In this implementation example, estimating a stabilized response value, corresponding to a value that would have been measured after a nominal wait time (greater than said reduced wait time), based on the anticipatory response value measured at the reduced wait time, is carried out as follows:

One or more curves of response values measured during the learning phase, are used as reference curves. The anticipatory response value measured at the wait time t_{reduced} is compared to the response values of the reference curves at said wait time t_{reduced} so as to establish a sub-ratio for each reference curve. The sub-ratio for the reference curve of index j can be calculated as follows:

$${r}_{j} = \frac{1}{1 + \vert {Vt}_{reduced} - {C}_{j} {t}_{reduced} \vert} \qquad [ Math . 6 ]$$

Vt_{reduced} being the anticipatory response value and Cⱼt_{reduced} the response value at t_{reduced} of the reference curve j.

These different sub-ratios make it possible to build a weighted mean curve based on the different reference curves. The closer the anticipatory response value to the response value at t_{reduced} of a reference curve, the more the weighted mean curve will follow the same evolution as this reference curve.

The response value at the time t of the weighted mean curve can be defined as follows:

$${C}_{wm} t = \frac{{\sum }_{j = 1}^{m} {r}_{j} \times {C}_{j} t}{{\sum }_{j = 1}^{m} {r}_{j}} \qquad [ Math . 7 ]$$

m being the number of reference curves and Cⱼt the response value of the reference curve j at the time t.

A primary ratio can then be established as follows:

$$R = \frac{{Vt}_{reduced}}{{C}_{wm} {t}_{reduced}} \qquad [ Math . 8 ]$$

C_{wm}t_{reduced} being the response value of the weighted mean curve at the wait time t_{reduced}.

The estimated stabilized response value can be calculated as follows:

$${V}_{estimated} {t}_{nominal} = R \times {C}_{wm} {t}_{nominal} \qquad [ Math . 9 ]$$

The estimated curve, represented in FIG. 6, corresponds to the evolution of the weighted mean curve C_{wm}t multiplied by the primary ratio R according to the wait time. This estimated curve is therefore composed of points obtained from an interpolation between different points measured at a given wait time.

In one implementation example, a single reference curve is used to carry out the estimation of the stabilized response value. This single reference curve may be obtained from a single measurement per wait time for a single component or be an unweighted mean of several values measured per wait time for one or more components. This single reference curve may also be a weighted mean of several response values per wait time, the weighting of a response value being defined for example according to a distance between the response value and the mean or the median of the response values. It is also possible to take into account all the response values measured or merely some values after values deemed to be invalid (because they are too far from the mean value for example) have been filtered. In this implementation example, only the primary ratio is used to carry out the estimation of the stabilized response value.

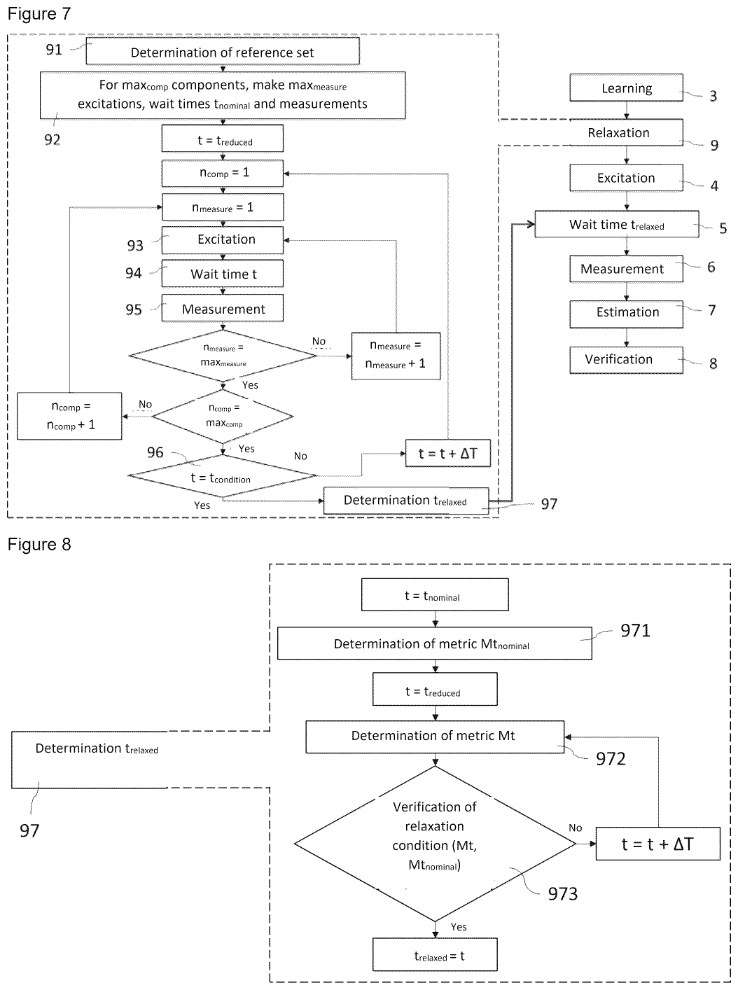

FIG. 7 schematically represents an example of test method according to the invention. This example includes the steps of the test method represented by FIG. 1 as well as a relaxation step 9. This step makes it possible to adjust the wait time used by the test method in step 5 to the conditions of implementation of the test method on the production or assembly line. Indeed, the test device and many other variables can change with respect to the conditions of implementation of the learning phase 3, which results in a degradation of the reliability of the test method using the reduced wait time. This relaxation step 9 adjusts the wait time of the step 5 by replacing the reduced wait time obtained from the learning phase 3 by a relaxed wait time. FIG. 7 represents the sub-steps of the relaxation phase 9. The relaxation phase 9 starts with a step 91 of determining the set of reference components for relaxation. This step makes it possible to select components for which the quality is deemed to be satisfactory on the production line. This means within the scope of operational implementation of the test method according to the invention. This step consists, generally, of subjecting the components to a test method using a nominal wait time. The set of reference components for relaxation is sometimes referred to as “reference set for relaxation” hereinafter in the description. A measurement step 92 at the nominal wait time is then carried out. It makes it possible to collect the data required for the subsequent establishment of a value of a metric calculated based on the response values at the nominal wait time for relaxation. This step consists, for each component of the reference set for relaxation, of subjecting at least one of the terminals of the component to an excitation, then waiting for the nominal wait time, then measuring the response of the component at at least one of its terminals.

In one implementation example, the steps of determining 91 the reference set and measuring 92 at the nominal wait time are carried out simultaneously.

The wait time, at the step 94 after the step of excitation 93 of a component, is increased progressively by a value of a time step Δt and the response values are measured 95 until verification 96 of a condition indicating that an end-of-relaxation wait time t_{condition} has been reached. In one implementation example, the end-of-relaxation wait time is proportional to the nominal wait time.

$${t}_{condition} = 0.5 \times {t}_{nominal} \qquad [ Math . 10 ]$$

The determination 97 of the relaxed wait time is then carried out.

FIG. 8 schematically represents an example of determination 97 of the relaxed wait time. The determination 971 of a value of the relaxation metric is carried out based on the response values of the components of the reference set for relaxation at the nominal wait time. In one implementation example, the relaxation metric can be a mean of the response values or a variance of the response values. Several relaxation metrics can also be determined so that, subsequently, a combination of these metrics is used to form a relaxation condition. In one implementation example, the same metrics are used for the learning phase 3 and for the relaxation phase 9. Then, during a progressive increase in the wait time t (according to a time step Δt) from the reduced wait time, the determination 972 of a value of the relaxation metric is carried out based on the response values of the components of the reference set for relaxation at the wait time t. A step of verifying 973 a relaxation condition, established based on the previously determined relaxation metrics, is carried out. The relaxed wait time is the first wait time from which the relaxation condition is fulfilled.

In one implementation example, the reduction condition, used in the learning phase, and the relaxation condition, used in the relaxation phase, are identical.

In one implementation example, the measurements of the relaxation phase stop advantageously when the relaxed wait time has been reached. This means that the greatest wait time for which measurements are made during the relaxation phase t_{condition} is equal to the relaxed wait time t_{relaxed}. In this case, the steps of determining 97 the relaxed wait time t_{relaxed} and verifying 96 the end-of-measurement condition of the relaxation phase are carried out simultaneously. In this case also, the value of the greatest wait time for which measurements are made during the relaxation phase t_{condition} is reassessed at each iteration of increasing the wait time t of the relaxation phase 9. The relaxation phase being carried out on the production line, it is particularly advantageous to make the fewest measurements possible in this phase in order to limit productivity loss as much as possible.

In one implementation example, the relaxation phase is triggered by one of the following events:
first launch of the test method in a production line of an electronic component or in an assembly line using an electronic component,
a maintenance procedure on a testing system carrying out the test method is finished,
a production line operative signals a change of electronic component batch,
a successive number of components, for which the quality is deemed to be unsatisfactory, has been reached,
a proportion of components, for which the quality is deemed to be unsatisfactory, has been reached.

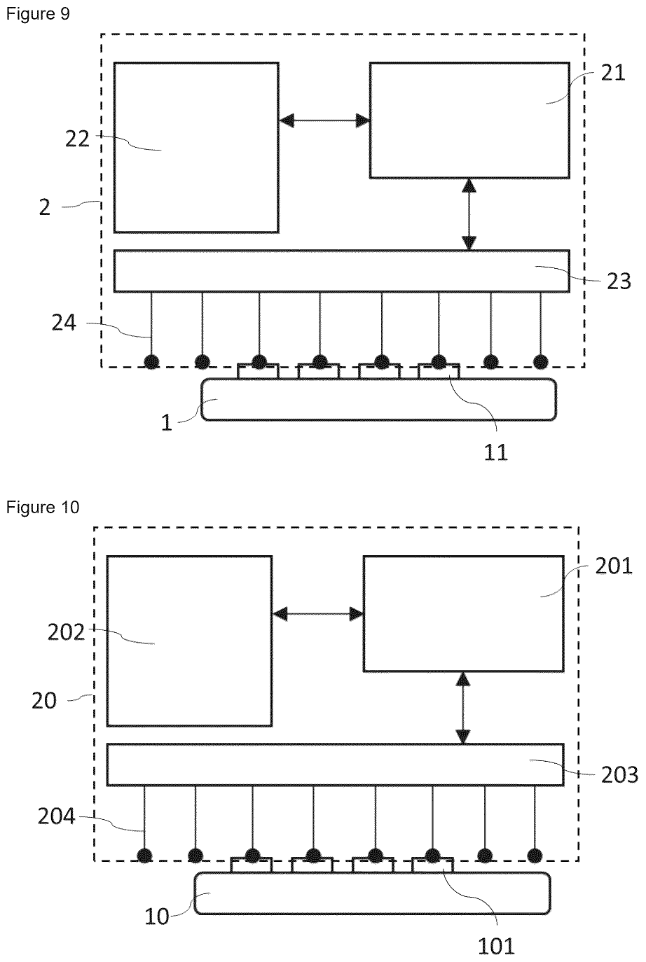

FIG. 9 schematically represents an example of device 2 according to the invention. This device 2 includes an electronic memory 22 containing a computer program product in the form of a set of code instructions to be run to implement the steps of the test method according to one of the implementation examples. This device 2 also includes a processor 21 which runs the instructions of the computer program product and controls the test module 23 having interfaces 24 for exciting an electronic component 1, and/or measuring the responses of the electronic component 1. FIG. 9 also represents the interfaces, also referred to as terminals 11, of the electronic component which can be placed in contact with the interfaces 24 of the test module 23.

FIG. 10 schematically represents an example of device 20 intended to implement the learning phase according to the invention. This device 20 includes an electronic memory 202 containing a computer program product in the form of a set of code instructions to be run to implement the steps of the learning phase according to any one of the implementation examples described above. This device 20 also includes a processor 201 which runs the instructions of the computer program product and controls the test module 203 having interfaces 204 for exciting an electronic component 10 and/or measuring the responses of the electronic component 10. FIG. 10 also represents the interfaces, also referred to as terminals 101, of the electronic component which can be placed in contact with the interfaces 204 of the test module 203.

Therefore, it is understood that the invention also relates to a training method for training the learning algorithm according to the invention, said training method including the following steps:
determining 31 a set of reference components including one or more components,
decreasing a wait time iteratively from a nominal wait time,
measuring 34 several response values of each component of the set of reference components, for each wait time,
determining 36 a reduced wait time based on the measurements obtained,
using the measurements obtained as learning data to train 37 a learning algorithm to estimate a stabilized response value, corresponding to a value that would have been measured after the nominal wait time, based on an anticipatory response value measured at the reduced wait time.

Such steps allow the training method to produce measurements, then use these measurements to train a learning algorithm. Said learning algorithm is capable of being used in an electronic component test method making it possible to reduce the time required for testing an electronic component without modifying the acceptance conditions of the electronic component.

1-14. (canceled)

15. An electronic component test method, comprising:
excitation of at least one of terminals of a component;
after a reduced wait time, measuring an anticipatory response time at said at least one of the terminals of the component;
estimating a stabilized response value, corresponding to a value that would have been measured after a nominal wait time, based on the anticipatory response value, the nominal wait time being greater than the reduced wait time;
verifying an acceptance condition, for the stabilized response value estimated, for assessing a quality of the component; and
wherein the estimation of the stabilized response value based on the anticipatory response value is carried out by a learning algorithm previously trained, during a learning phase, by:
determining a set of reference components comprising one or more components;
decreasing a wait time iteratively from the nominal wait time;
measuring response values of each component of the set of the reference components, for each wait time;
determining the reduced wait time based on the response values measured; and
using the response values measured as learning data to train the learning algorithm to estimate the stabilized response value based on the anticipatory response value measured at the reduced wait time.

16. The test method of claim 15, wherein said determining the reduced wait time based on the response values measured comprises:
defining at least one metric for which a value is determined, for a given wait time, based on at least a portion of the response values measured at the given wait time;
determining a value of said at least one metric for the nominal wait time;
for said each wait time less than the nominal wait time:
determining a value of said at least one metric for said each wait time; and
verifying a reduction condition according to the value of said at least one metric for the nominal wait time and the value of said at least one metric for said each wait time; and
wherein the reduced wait time is greater than or equal to a shortest wait time from which the reduction condition is fulfilled and less than or equal to the nominal wait time.

17. The test method of claim 16, wherein said at least one metric comprises a variance.

18. The test method of claim 15, wherein the learning algorithm is a machine learning algorithm.

19. The test method of claim 15, wherein the learning algorithm performs at least one interpolation.

20. The test method of claim 19, wherein the interpolation is at least one of a polynomial interpolation and a cubic spline interpolation.

21. The test method of claim 19, wherein the learning algorithm performs an interpolation between measurement points corresponding to different wait times.

22. The test method of claim 19, wherein the learning algorithm performs an interpolation between measurement points at a given wait time.

23. The test method of claim 15, further comprising a relaxation phase which replaces the reduced wait time with a relaxed wait time.

24. The test method of claim 23, wherein the relaxation phase comprises:
determining a set of reference components for relaxation comprising one or more components;
measuring response values of each component of the set of reference components for relaxation at the nominal wait time;
increasing a second wait time iteratively from the reduced wait time;
measuring second response values of each component of the set of reference components for relaxation, for each second wait time; and
determining the relaxed wait time based on the second response values measured.

25. The test method of claim 24, wherein said determining the relaxed wait time comprises:
defining at least one relaxation metric for which a value is determined, for a given wait time, based on at least a portion of the second response values measured at the given wait time;
determining a value of said at least one relaxation metric for the nominal wait time;
for each second wait time greater than or equal to the reduced wait time:
determining a value of said at least one relaxation metric for said each second wait time;
verifying a relaxation condition according to the value of said at least one relaxation metric for the nominal wait time and the value of said at least one relaxation metric for said each second wait time; and
wherein the relaxed wait time is greater than or equal to a shortest second wait time from which the relaxation condition is fulfilled and less than or equal to the nominal wait time.

26. The test method of claim 25, wherein said at least one relaxation metric comprises a variance.

27. A device comprising at least one test module, at least one processor to control said at least one test module, at least one electronic memory, and a computer program product, stored in said at least one electronic memory executable by said at least one processor, comprising a set of code instructions to implement the test method of claim 15.

28. A device comprising at least one test module, at least one processor to control said at least one test module, at least one electronic memory, and a computer program product, stored in said at least one electronic memory executable by said at least one processor, comprising a set of code instructions to implement the following:
determining a set of reference components comprising one or more components;
decreasing a wait time iteratively from a nominal wait time;
measuring response values of each component of the set of reference components, for each wait time;
determining a reduced wait time based on the response values measured; and
using the response values measures as learning data to train a learning algorithm to estimate a stabilized response value, corresponding to a value that would have been measured after the nominal wait time, based on an anticipatory response value measured at the reduced wait time.
